(19) United States
(12) Patent Application Publication
(10) Pub. No.: US 2003/0080755 A1
(43) Pub. Date: May 1, 2003

(54) Proximity sensor and object detecting device

(75) Inventor: Tadashi Kobayashi, Tokyo (JP)

Correspondence Address: KANESAKA AND TAKEUCHI, 1423 Powhatan Street, Alexandria, VA, 22314, US

(73) Assignee: KABUSHIKI KAISHA HONDA DENSHI GIKEN

(21) Appl. No.: 10/283,098

(22) Filed: Oct. 30, 2002

(30) Foreign Application Priority Data
Oct. 31, 2001 (JP) 2001-335801
Oct. 15, 2002 (JP) 2002-300193

(51) Int. Cl. G01R 27/26

(52) U.S. Cl. 324/658

(57) ABSTRACT

In a proximity sensor, in order that it is not affected by a cable length and an environment of a setting place or the like, and that it is extremely stable in operation, and that it can be used nearing in a maintenance-free state, there are included a detecting electrode arranged in an object detecting area and made of a metal plate formed like a plate; a charge system with a direct current power source; a discharge system with a current detecting unit; and a switch for alternately switching the charge system and the discharge system to the detecting electrode by a specified switching frequency, and an electrostatic capacity between a detected object and the detecting electrode is detected as current flowing in the discharge system.

### TECHNICAL FIELD

The present relates to a proximity sensor and an object detecting device to which this is applied, and more particularly, relates to a proximity sensor in which a detecting sensitivity is not affected by the environment of the setting place, a lead cable or the like, and which can be used in the state where adjustment is hardly necessary. The present invention is applied as an object detecting device in various field including an opening and closing control sensor for an automatic door.

### BACKGROUND ART

Most of proximity sensors are the high frequency oscillating type, and comprise: a sensor part of the electrostatic capacity which is composed of a pair of metal detecting plates set, for example, at a gateway of an automatic door, a parking lot or the like; and an oscillation detecting part which is connected to the sensor part through a coaxial cable to create an analog voltage, and it is arranged to detect an object such as a human body or a vehicle by comparing the analog voltage from the oscillation detecting part with the detection signal obtained from the sensor part (for example, refer to Japanese Patent published under Publication No. 7-29467, Japanese Patent published under Publication No. 7-287793).

However, the high frequency proximity sensor has the following practical problems to be solved. That is, the electrostatic capacity of the sensor part changes by receiving the effects of the temperature and humidity (moisture) at the setting place, and the metal parts existing at the periphery or the like, and besides, by the lead wire length of the cable connecting the sensor part and the oscillation control part, it also receives the effects of the impedance component parasitic in the cable, and the detecting sensitivity delicately changes.

Accordingly, even if the matching between the sensor part and the oscillation control part is taken at the factory shipping step, in many cases, the lead wire length of the cable is different for each setting place, and therefore, re-adjustment is each time necessary. Furthermore, sometimes, by the environmental change (temperature, or humidity or the like) of the setting place, the operation point changes with time, and therefore, the maintenance is needed regardless of a regular one or an irregular one.

Especially, in the case of a device for an automatic door, the detected object is a human body, person, and therefore, from the viewpoint of the safety, the maintenance is indispensable. From such a reason, many proposals have been made on the high frequency proximity sensor, but it is the actual situation that they have infrequently been put to the practical use.

### SUMMARY OF THE INVENTION

Accordingly, it is an object of the present invention to provide a proximity sensor, which is not affected by the cable length, the environment of the setting place or the like, and is extremely stable in the operation, and can be used almost in the maintenance-free state.

In order to attain the above described object, the present invention includes: a detecting electrode arranged in the object detecting area and made of a metal plate formed like a plate; a charge system with a direct current power source; a discharge system with current detecting means; and a switch for alternately switching the above described charge system and the above described discharge system to the above described detecting electrode by a specified switching frequency, wherein the electrostatic capacity between the detected object and the above described detecting electrode is detected as the current Is flowing in the above described discharge system.

As a preferred embodiment of the present invention, the switching frequency of the switch is, for example, set to about tens kHz to hundreds kHz. Letting the voltage of the direct current power source be Vo and the electrostatic capacity between the detecting electrode and the object (for example, a human body) be Cs, the electric charge Q (unit: coulomb) supplied to the detecting electrode is expressed by Q=Cs·Vo×fo.

On the other hand, letting time be t, the electric charge Q emitted from the detecting electrode to the discharge system is expressed by Q=Is·t. Accordingly, the expression of Is=(Cs·Vo×fo)/t is established, and when considering the current, t=1 sec, and therefore, Is=Cs·Vo×fo is found.

That is, the basic principle of the present invention is the charge and discharge of the electrostatic capacity Cs of the detecting electrode, and the current Is flowing in the discharge system mainly relies on only the electrostatic capacity Cs of the detecting electrode, and therefore, the object detecting sensitivity is not affected by the wiring length of the cable connecting the detecting electrode and the detector circuit (control part) or the like.

In the actual use, the change of the stray capacitance between the detecting electrode and the peripheral ground may cause an error detection, and therefore, a ground electrode is provided on the rear side of the detecting electrode, but if doing so, an extremely large electrostatic capacity Co by the ground electrode is connected in parallel to the above described electrostatic capacity Cs.

In order to remove the effects to the detecting sensitivity of the electrostatic capacity Co caused by providing this ground electrode, as a first method, it is sufficient to provide a current source for absorbing the current Io of the increase flowing in the discharge system because of the electrostatic capacity between the ground electrode and the detecting electrode, in parallel to the current detecting means.

Furthermore, as a second method of removing the effects to the detecting sensitivity of the electrostatic capacity Co caused by providing the ground electrode, it is also possible to provide a capacitor with the same capacity as the electrostatic capacity Co between the ground electrode and the detecting electrode, a second direct current power source with the polarity reversed to that of the direct current power source of the charge system, and a second switch for alternately switching the second direct current power source and the discharge system to the above described capacitor in synchronization with the above described switch, to the discharge system. In that case, it is also possible to use a pair of electrode plates made of the same combination as the detecting electrode and the ground electrode as the alternative to the above described capacitor.

The detecting electrode and the charge system and discharge system are connected by a coaxial cable, and therefore, it is supposed that depending on the cable length thereof or the bending state, sometimes, the change of the electrostatic capacity included in that cable appears more largely than the electrostatic capacity change because of the approach of an object.

In order to prevent this, the present invention includes: a detecting electrode arranged in the object detecting area and made of a metal plate formed like a plate; an earthed ground electrode arranged facing to the same detecting electrode; a charge system with a direct current power source; a discharge system with current detecting means; and a double shield wire with an inside skin shield and an outside skin shield around a central conductor, wherein the above described detecting electrode is connected to one end of the above described central conductor, and on the other end side thereof, a first switch for alternately switching the above described charge system and the above described discharge system to the same central conductor by a specified switching frequency is provided, and at the same time, to the above described inside skin shield, a second switch for alternately switching the same inside skin shield to the above described charge system and the earth in synchronization with the above described first switch is provided, and the above described ground electrode is connected to the above described outside skin shield.

According to this, the inside skin shield and the central conductor is always kept at the same electric potential, and therefore, no electrostatic capacity is produced between them. More preferably, it is recommended that a guard electrode is set between the above described detecting electrode and the above described ground electrode, and the above described guard electrode is connected to the above described inside skin shield.

Next, in order to detect the approaching object by a high sensitivity, the present invention includes: a first and a second detecting electrodes both of which are made of a metal plate with the same size formed like a plate, and are arranged in parallel approximately on the same plane in the object detecting area; a charge system with a direct current power source; a discharge system with current detecting means; and switch means for alternately switching both the above described first and second detecting electrodes by a specified switching frequency to the above described charge system and the above described discharge system.

For example, if a positive pole voltage is supplied to one detecting electrode and at the same time, to the other detecting electrode, a negative pole voltage is supplied, the current flowing from one detecting electrode to the above described discharge system becomes +Isa, and the current flowing from the other detecting electrode to the above described discharge system becomes −Isb, and if the electrostatic capacity of each detecting electrode is balanced, the current flowing in the above described discharge system becomes 0. If an object approaches to collapse the balance, a current of the difference of the electrostatic capacity flows in the above described discharge system, and consequently, the object can be detected.

Furthermore, in the case where the same pole voltage is supplied to the first and second detecting electrodes, it is sufficient to perform the subtraction of the current Isa obtained from one detecting electrode and the current Isb obtained from the other detecting electrode, by a subtractor in the discharge system.

Next, in order to remove the external induction noise, the present invention is a proximity sensor including: a first and a second detecting electrodes both of which are made of a metal plate with the same size formed like a plate and are arranged in parallel approximately on the same plane in the object detecting area; a charge system with a direct current power source; a discharge system with current detecting means; and main switch means for alternately switching both the above described first and second detecting electrodes by a specified switching frequency to the above described charge system and the discharge system, wherein the above described discharge system is provided in parallel between the above described main switch means and the above described current detecting means, and comprises: a first discharge circuit connected to the above described first detecting electrode side; and a second discharge circuit connected to the above described second detecting electrode side, and to either the above described discharge circuits, a signal reversing circuit made of a capacitor and a sub switch which alternately cuts off both ends of the same capacitor from the same discharge circuit and connects them to the earth terminal is provided, and each time the above described main switch means is switched, the polarity of the above described capacitor is reversed by the above described sub switch.

Furthermore, as another embodiment, the present invention includes the proximity sensor comprising: a first and a second detecting electrodes both of which are made of a metal plate with the same size formed like a plate and are arranged in parallel approximately on the same plane in the object detecting area; a drive electrode arranged facing commonly to each of these detecting electrodes; a charge system with a direct current power source, a discharge system with a condenser and current detecting means; a first switch for selectively connecting at least one pole of the above described direct current power source to the above described drive electrode by a specified switching frequency; a second switch for alternately connecting each of the above described detecting electrodes together in synchronization with the same first switch to the above described one pole of the above described direct current power source and the above described condenser; and a third switch for alternately connecting the above described condenser to the above described each detecting electrode and the above described current detecting means in synchronization with the above described each switch.

In this case, it is preferable that between the above described first and second detecting electrodes and the above described drive electrode, a first and a second guard electrodes made of a metal plate with the same size as the above described detecting electrode are arranged, and the above described first detecting electrode and the above described first guard electrode, and the above described second detecting electrode and the above described second guard electrode are respectively connected through an operation amplifier with an amplification factor of one time, and according to this, the object detecting sensitivity can be made higher.

Furthermore, as another embodiment, the present invention includes the proximity sensor comprising: a first and a second detecting electrodes both of which are made of a metal plate with the same size formed like a plate, and are arranged in parallel approximately on the same plane in the object detecting area; a drive electrode arranged facing commonly to each of these detecting electrodes; a charge system with a direct current power source; a discharge system with a first and a second condensers and current detecting means; a first switch for selectively connecting at least one pole of the above described direct current power source to the above described drive electrode by a specified switching frequency; a second switch for the synchronous detection for alternately exchanging and connecting each of the above described detecting electrodes in synchronization with the same first switch to both the above described detecting electrodes to both poles of the above described first condenser; and a third switch for alternately connecting the above described second condenser to the above described first condenser and the above described current detecting means in synchronization with the above described each switch. Furthermore, it is preferable that the switching frequency of the above described third switch is set at two times the switching frequency of the above described first and second switches.

In the present invention, an object detecting device is included, which comprises a plurality of combinations of the above described each proximity sensor, and has such a basic configuration that each detecting electrode of the adjacent combination is alternately arranged along a specified plane or a curved surface.

In this object detecting device, in order to remove the neutral zone and at the same time, to decrease the radiation noise, it is preferable that a drive voltage with a different polarity is applied to each of the electrodes with odd ordinal numbers and even ordinal numbers. This object detecting device is particularly suitable for a sensor of the leading edge of door leaf of an automatic door or a mat sensor set on the entrance floor surface of an automatic door.

Furthermore, the present invention includes, as another application example, an object detecting device wherein from a detected object, an individual detected information thereof can be obtained. This object detecting device comprises: a sensor surface including a plurality of detecting electrodes arranged in parallel along the line direction and the row direction on the same plane; a drive electrode arranged approximately through the whole surface on the rear side of the above described sensor surface through a dielectric layer; a charge system with a direct current power source; a discharge system with current detecting means; a plurality of charge wirings wired along either the line direction or the above described row direction of the above described sensor surface on the anti-sensor surface side of the above described drive electrode and a plurality of discharge wirings wired along the other; a detecting electrode switching switch for selectively connecting the above described each detecting electrode to either the above described charge wiring or the above described discharge wiring separately; a first scanner switch for sequentially connecting the above described each charge wiring to the direct current power source of the above described charge system; a second scanner switch for sequentially connecting the above described each discharge wiring to the current detecting means of the above described discharge system; a drive electrode switching switch for selectively connecting the above described drive electrode to either the direct current power source of the above described charge system or the earth; and control means for controlling the above described each switch, wherein the above described control means performs: a first step of switching the above described drive electrode switching switch to the above described direct current power source side each time switching the above described first scanner switch to connect the above described charge wiring to the above described direct current power source one by one, and at the same time, of switching the above described detecting electrode switching switch selected by the above described first scanner switch and existing along the above described charge wiring to the same charge wiring side; a second step of switching the above described drive electrode switching switch to the above described earth side after the above described first step, and at the same time, of switching the above described detecting electrode switching switch switched to the above described charge wiring side at the above described first step, to the above described discharge wiring side; and a third step of sequentially switching the above described second scanner switch to go around after the above described second step.

According to this object detecting device, for example, by laying and arranging the detecting electrode on the floor surface, not only the existence of a human body but also the moving direction thereof can be detected. Furthermore, for example, by making the individual detecting electrode have a size approximately equal to the picture element of a CCD camera, for example, a human fingerprint or the like can also be detected.

Furthermore, in the present invention, it is preferable that in the viewpoint of decreasing the interference to the radio receiver or the like existing at the periphery, the switching frequency of the switch for switching the above described charge system and the above described discharge system is a complex frequency including a plurality of different frequencies.

### BRIEF DESCRIPTION OF DRAWINGS

The present invention will be described by embodiments by referring to appended drawings. The drawings are as follows:

FIG. 1 is a typical figure showing a first basic embodiment of the present invention;

FIG. 2 to FIG. 4 are typical drawings respectively showing a first method of removing effects by an electrostatic capacity of a ground electrode, a second method, and a third method;

FIG. 5 and FIG. 6 are typical drawings showing a first method of removing effects by the electrostatic capacity of a cable, and a second method;

FIG. 7 is a typical drawing showing a second embodiment of a present invention;

FIG. 8 is a typical drawing showing one example of the arrangement of a detecting electrode of the above described second embodiment;

FIG. 9 is a circuit diagram for describing a removing method of an external induction noise in the above described second embodiment;

FIG. 10A and FIG. 10B are circuit diagrams showing compensating means applied for the removal of the above described external induction noise;

FIG. 11 is a circuit diagram showing a third embodiment of the present invention;

FIG. 12A to FIG. 12E are operation explanatory drawings of the above described third embodiment;

FIG. 13 and FIG. 14 are circuit diagrams respectively showing deformed examples of the above described third embodiment;

FIG. 15 is a circuit diagram showing a fourth embodiment of the present invention;

FIG. 16 is a typical drawing showing an operational principle of the above described fourth embodiment;

FIG. 17A and FIG. 17B are operation explanatory drawings of the above described fourth embodiment;

FIG. 18 is a waveform drawing showing a synchronous detection waveform of the above described fourth embodiment;

FIG. 19 is a circuit diagram showing a deformed example of the above described fourth embodiment;

FIG. 20 is a typical drawing showing an arrangement of the detecting electrode for achieving decrease of radiation noise;

FIG. 21A to FIG. 21C are typical drawings exemplifying the use of the present invention;

FIG. 22 is a typical perspective view showing a configuration of a plane sensor according to the present invention;

FIG. 23 is a circuit diagram of the above described plane sensor; and

FIG. 24 is a waveform drawing showing a preferable switching frequency of a switch for switching a charge system and a discharge system in the present invention.

### DETAILED DESCRIPTION

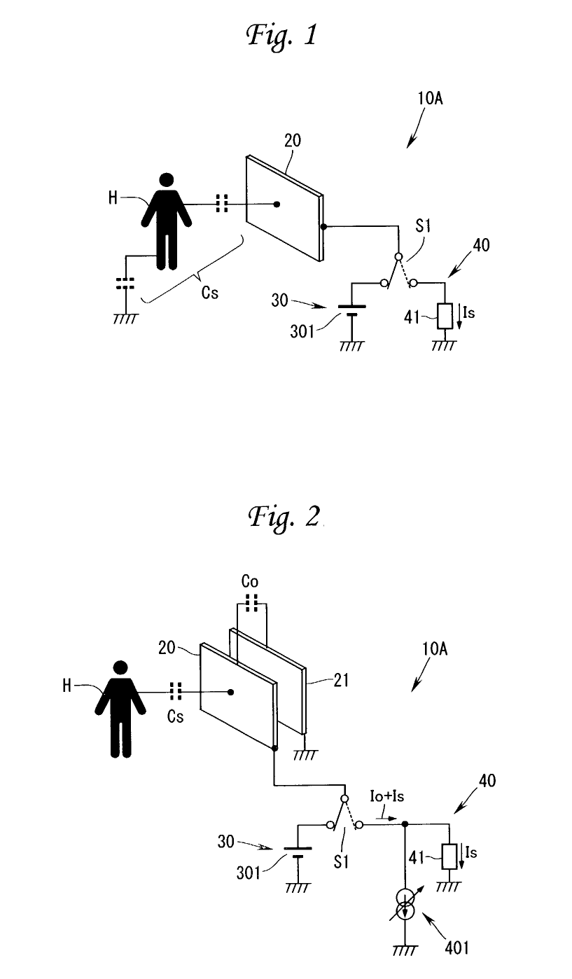

First, by referring to FIG. 1, a basic configuration of a proximity sensor 10A according to the present invention will be described.

This proximity sensor 10A comprises: a detecting electrode 20 arranged in the object detecting area and made of a metal plate formed like a plate; a charge system 30 with a direct current power source 301; a discharge system 40 with current detecting means 41 made of, for example, a current-voltage converter; and a switch S1 for alternately switching the charge system 30 and the discharge system 40 to the detecting electrode 20 by a specified switching frequency, and it detects the electrostatic capacity between a detected object H such as a human body and the electrode 20 as a current Is flowing in the discharge system.

In this example, the switch S1 is an analog switch, and the switching frequency fo thereof is set at, for example, about tens kHz to hundreds kHz. Letting the voltage of the direct current power source 301 be Vo and the electrostatic capacity between the detecting electrode 20 and the detected object H be Cs, the electric charge Q (unit: coulomb) supplied to the detecting electrode is expressed by Q=Cs·Vo×fo. Furthermore, the current when an electric charge of one coulomb is transferred in one second is 1 A.

On the other hand, letting time be t, the electric charge Q emitted from the detecting electrode to the discharge system is expressed by Q=Is·t. Accordingly, the expression of Is=(Cs·Vo×fo)/t is established, and when considering the current, t=1 sec, and therefore, Is=Cs·Vo×fo is made.

Thus, the basic principle of the present invention is the charge and discharge of the electrostatic capacity Cs possessed by the detecting electrode 20, and the current Is flowing in the discharge system exclusively relies on only the electrostatic capacity Cs of the detecting electrode 20, and therefore, theoretically, the object detecting sensitivity is not affected by the wiring length of the cable connecting the detecting electrode and the detecting circuit (controller) or the like.

However, in the actual use, in some cases, the change of the stray capacitance between the detecting electrode 20 and the peripheral ground may cause an error detection, and therefore, as show in FIG. 2, a ground electrode 21 is provided on the rear side of the detecting electrode 20, but if doing so, an extremely large electrostatic capacity Co by the ground electrode 21 is connected in parallel to the above described electrostatic capacity Cs. According to the experiment, the electrostatic capacity Cs is about 0.1 pF, and on the other hand, the electrostatic capacity Co shows a value of about 100 pF.

In order to remove the effects to the detecting sensitivity of the electrostatic capacity Co produced by providing this ground electrode 21, in this embodiment, a current source 401 for absorbing the current Io of the increase flowing in the discharge system 40 resulting from the above described electrostatic capacity Co is provided in parallel to the discharge system 40, and it is arranged to detect only the current Is by the above described electrostatic capacity Cs, by the current detecting means 41 of the discharge system 40.

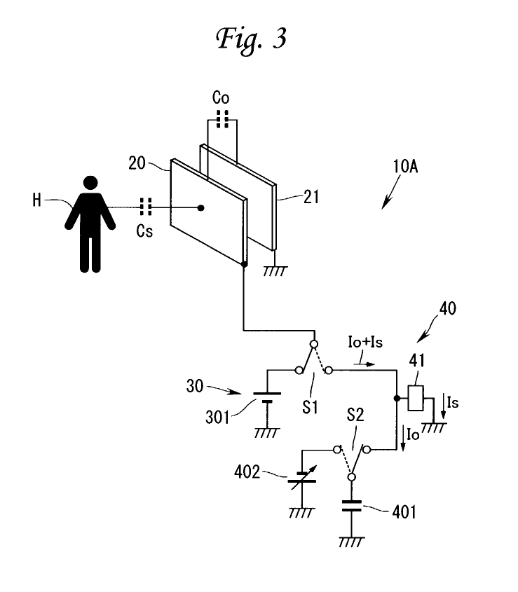

As another method of removing the current Io by the electrostatic capacity Co, as shown in FIG. 3, it is also possible to provide a capacitor 401 with the same capacity as the electrostatic capacity Co between the ground electrode 21 and the detecting electrode 20, a second direct current power source 402 with the same voltage as the direct current power source 301 of the charge system 30 and with the reverse polarity, and a second switch S2 for alternately switching the direct current power source 402 and the discharge system 40 to the capacitor 401 in synchronization with the above described switch S1, to the discharge system 40.

The switch S2 is switched to the discharge system 40 side accompanied with the switching of the switch S1 to the discharge system 40 side, and consequently, the electric charge of the current Io is accumulated in the capacitor 401. Next, the switch S2 is switched to the direct current power source 402 side accompanied by the switching of the switch S1 to the charge system 30 side. Consequently, a reverse voltage is applied to the capacitor 401, and therefore, the electric charge accumulated in the capacitor 401 disappears.

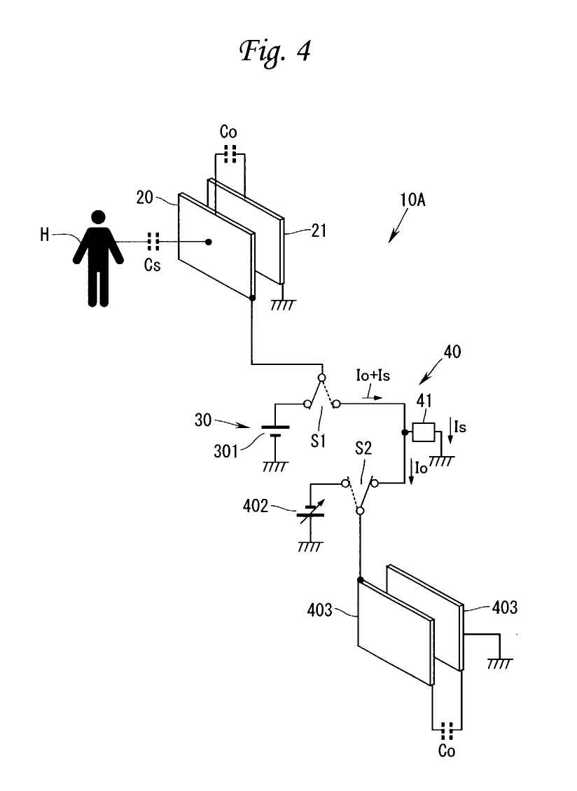

Thus, the current Io by the electrostatic capacity Co is cancelled, and only the current Is by the electrostatic capacity Cs is detected by the current detecting means 41 of the discharge system 40, but as shown in FIG. 4, it is also possible to use a pair of electrode plates 403, 403 made of the same combination as the detecting electrode 20 and the ground electrode 21 and having the electrostatic capacity Co instead of the capacitor 401.

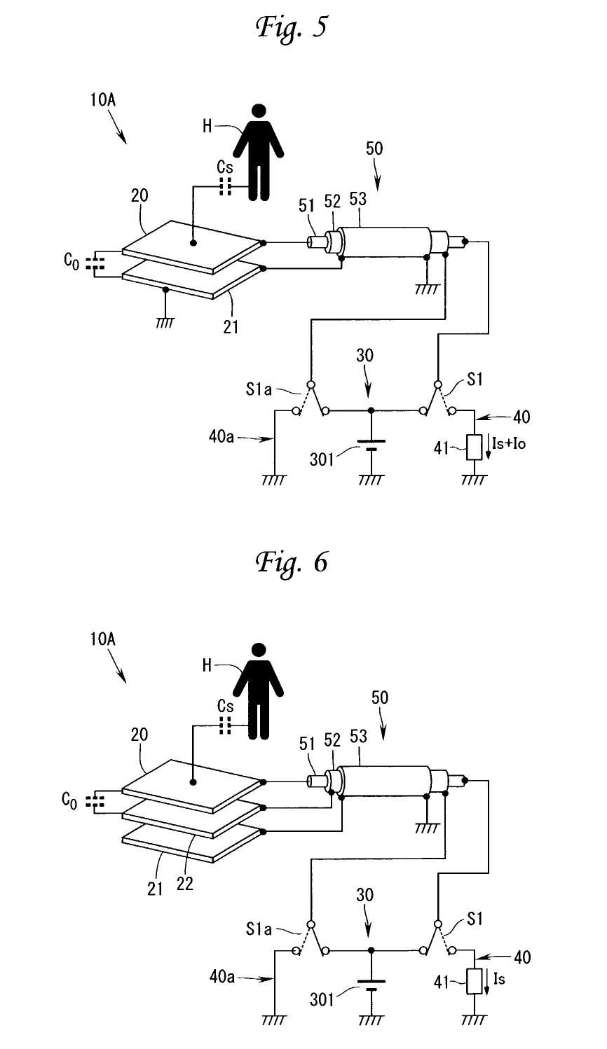

Next, as shown in FIG. 5, the detecting electrode 20 and the charge and discharge systems 30, 40 are connected by a cable 50, but depending on the cable length thereof, the bending state, or the circumferential temperature or the like, sometimes, the change of the electrostatic capacity possessed by the cable appears larger than the change of the electrostatic capacity by the approach of the detected object H, and an error detection or a sensitivity lowering is caused. Therefore, in this embodiment, a double shield wire is used for the cable 50, and the following countermeasures are taken.

To one end of a central conductor 51 of the double shield wire 50, a detecting electrode 20 is connected. The other end of the central conductor 51 can alternately be connected to the charge system 30 and the discharge system 40 through the switch S1. Furthermore, inside shield 52 of the double shield wire 50 can alternately be connected to the charge system 30 and a separately prepared discharge system 40a through a switch S1a. The ground electrode 21 is connected to an outside shield 53 of the double shield wire 50. Furthermore, the outside shield 53 is earthed.

The switch S1 and the switch S1a are switched synchronously. That is, it is arranged that when the switch S1 is connected to the direct current power source 301 of the charge system 30, the switch S1a is also connected to the direct current power source 301, and furthermore, it is arranged that when the switch S1 is switched to the discharge system 40 side, the switch S1a is also switched to the discharge system 40a side.

Consequently, the central conductor 51 and the inside shield 52 are kept always at the same electric potential, and therefore, without receiving the effects of the electrostatic capacity of the double shield wire 50, only the current Is by the electrostatic capacity Cs of the detecting electrode 20 can accurately be measured. This means that it becomes unnecessary to adjust the electrostatic capacity of the cable different according to the setting place, each time.

As a more preferable embodiment, as shown in FIG. 6, between the detecting electrode 20 and the ground electrode 21, a guard electrode 22 is arranged, and this guard electrode 22 is connected to the inside shield 52. Other configurations may be similar to those in FIG. 5. According to this, the detecting electrode 20 and the guard electrode 22 are always kept at the same electric potential, and the effects of the electrostatic capacity Co by the ground electrode 21 can also be removed, and therefore, the thickness of the total of the electrode can be made extremely thin by narrowing the space between each electrode plate.

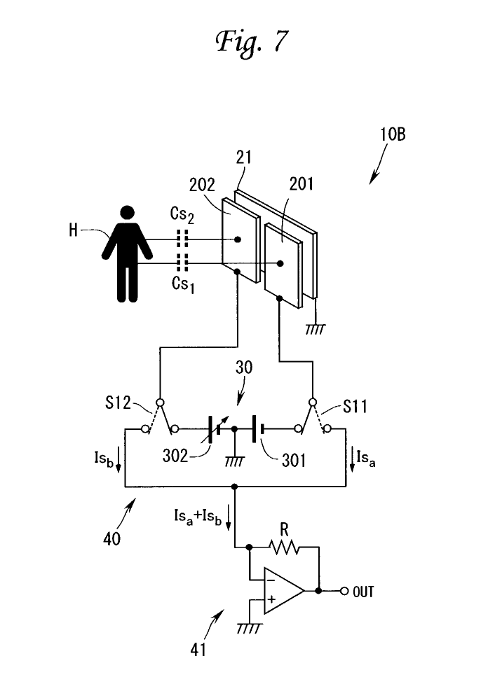

Next, by referring to FIG. 7, another proximity sensor 10B according to the present invention will be described. This proximity sensor 10B comprises a first and a second detecting electrodes 201, 202 both of which are made of a metal plate with the same size formed like a plate, and are set in parallel approximately on the same plane in the object detecting area. Furthermore, in this example, on the rear side of each of the detecting electrodes 201, 202, a ground electrode 21 common to them is arranged.

This proximity sensor 10B also comprises the charge system 30 and the discharge system 40, and in the case of this embodiment, to the charge system 30, a positive pole power source 301 and a negative pole power source 302 which have the same voltage (absolute value) are provided. Furthermore, the discharge system 40 is common to each of the detecting electrodes 201, 202, and to this discharge system 40, a current-voltage converter 41 as the current detecting means made of an operation amplifier is connected as the output means.

The first detecting electrode 201 is switched to the positive pole power source 301 and the discharge system 40 by the switch S11, and furthermore, the second detecting electrode 202 is switched to the negative pole power source 302 and the discharge system 40 by the switch S12. The switch S11 and the switch S12 are synchronously switched.

That is, when the first detecting electrode 201 is connected to the positive pole power source 301, the second detecting electrode 202 is also connected to the negative pole power source 302 at the same time, and furthermore, when the first detecting electrode 201 is connected to the discharge system 40, the second detecting electrode 202 is also connected to the discharge system 40 at the same time.

Here, letting the current supplied from the first detecting electrode 201 to the discharge system 40 be Isa and the current supplied from the second detecting electrode 202 to the discharge system 40 be Isb, the added current Isa+Isb thereof flows in the current-voltage converter 41. Furthermore, in this example, the current polarity is (+) in Isa and (−) in Isb.

For example, when no detected object H exists in the circumference, or when the detected object H exists at the center between the detecting electrodes 201, 202 so that the electrostatic capacity Cs1 of the first detecting electrode 201 is balanced with the electrostatic capacity Cs2 of the second detecting electrode 202, the added current Isa+Isb=0 is made, and accordingly, the output voltage also becomes 0.

On the other hand, for example, if the detected object H approaches to collapse the balance between the electrostatic capacity Cs1 and the electrostatic capacity Cs2, the added current Isa+Isb ≠0 is made, and letting the current of the difference thereof be Id and the return (amplified) resistance value of the operation amplifier be R, a voltage of Id×R is outputted from the current-voltage converter 41. Furthermore, in the −input terminal of the operation amplifier, an imaginary short is established, and therefore, the input impedance thereof is 0.

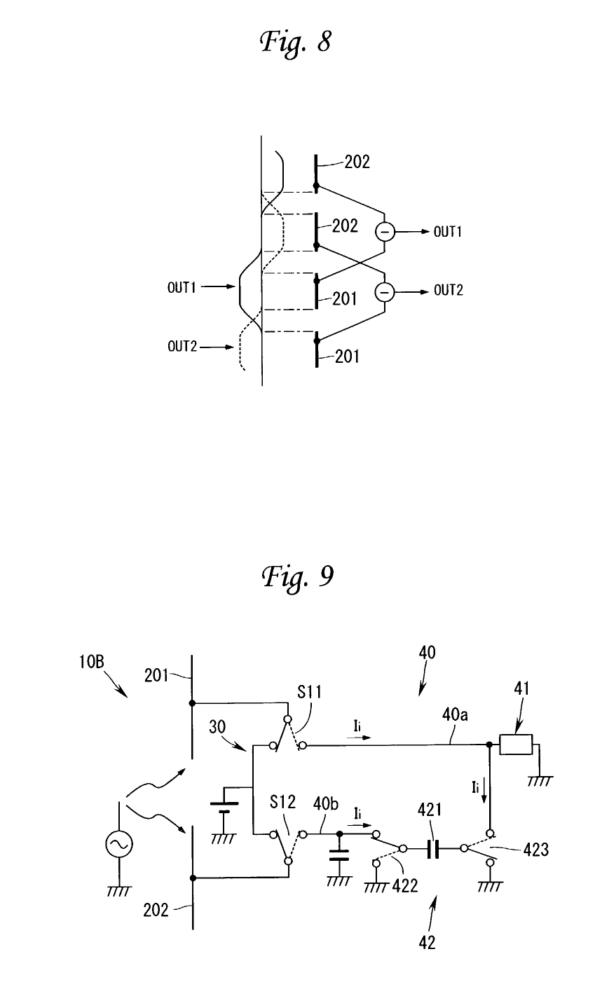

Furthermore, in case of using a plurality of combinations of these proximity sensors 10B, as shown in FIG. 8, by alternately arranging the positive pole side detecting electrodes 201 and the negative pole side detecting electrodes 202 of each combination, the output voltage of each combination changes to ±around 0 V. For example, when the change of 100 mV is made by the approach of the detected object H, if it is the change around 0V, the countermeasure can be made by a cheep 8 bit AID converter. Furthermore, by the alternate arrangement, the neutral zone can also be removed.

In the case of the above described embodiment, the power sources with different polarities are used for the first detecting electrode 201 and the second detecting electrode 202, but the same pole power source can also be used, and in that case, it is sufficient that the current Isa obtained from one detecting electrode 201 and the current Isb obtained from the other detecting electrode 202 are subjected to subtraction to pass through the current-voltage converter 41.

By the way, in the case of the proximity sensor 10B, the first detecting electrode 201 and the second detecting electrode 202 are arranged in parallel on the same plane, and therefore, for example, an external induction noise emitted from a fluorescent lamp or the like enters each of the detecting electrodes 201, 202 as the same phase. Letting the current for each one detecting electrode which appears in the discharge system 40 by that external induction noise be Ii, an induction noise current of Ii+Ii=2Ii flows in the current-voltage converter 41.

In order to cancel this induction noise current, as shown in FIG. 9, it is sufficient to provide a signal reversing circuit 42 in the discharge system 40, and next, this will be described. In the case of the proximity sensor 10B, in the discharge system 40 thereof, a first discharge circuit 40a leading to the current-voltage converter 41 from the switch S11 on the first detecting electrode 201 side and a second discharge circuit 40b leading to the current-voltage converter 41 from the switch S12 on the second detecting electrode 202 side are included in parallel, and in this embodiment, on the second discharge circuit 40b side therein, a signal reversing circuit 42 is provided.

This signal reversing circuit 42 has a capacitor 421, and on one pole side of this capacitor 421, a switch 422 is provided, which separates the same capacitor 421 from the second discharge circuit 40b to connect that to the earth. Furthermore, on the other pole side of the capacitor 421, a switch 423 is also provided, which separates the same capacitor 421 from the second discharge circuit 40b to connect that to the earth.

The switches 422, 423 are alternately switched in synchronization with the switches S11, S12. That is, when both the switches S11, S12 are switched to the charge system 30 side, for example, if one switch S422 is switched to the second discharge circuit 40b side, the other switch 423 is switched to the earth side.

On the contrary, when both the switches S11, S12 are switched to the discharge system 40 side, for example, if one switch S422 is switched to the earth side, the other switch 423 is switched to the second discharge circuit 40b side, and this switching operation is repeated.

According to this, for example, if both the switches S11, S12 are switched to the discharge system 40 side and accompanied with that, one switch 422 is switched to the second discharge circuit 40b side and the other switch 423 is switched to the earth side, an electric charge by the induction noise current Ii from the second detecting electrode 202 side is accumulated in the capacitor 421. Furthermore, in the first discharge circuit 40a, the induction noise current Ii appears as it is.

Next, if both the switches S11, S12 are switched to the charge system 30 side, this time, one switch 422 is switched to the earth side and the other switch 423 is switched to the second discharge circuit 40b side to reverse the polarity of the capacitor 421, and therefore, the induction noise current Ii of the first discharge circuit 40a is absorbed in the capacitor 421. Thus, the external induction noise entering the first detecting electrode 201 and the second detecting electrode 202 as the same phase is cancelled.

Furthermore, when both the switches S11, S12 are switched to the discharge system 40 side, in the case where one switch 422 is switched to the earth side and the other switch 423 is switched to the second detecting electrode 202 side, an electric charge by the induction noise current Ii from the first detecting electrode 201 side is accumulated in the capacitor 421.

Then, next, when both the switches S11, S12 are switched to the charge system 30, one switch 422 is switched to the second detecting electrode 202 side and the other switch 423 is switched to the earth side, and consequently, the polarity of the capacitor 421 is reversed, and at the same time, by the induction noise current Ii from the second detecting electrode 202 side, the electric charge of the capacitor 421 becomes 0 by the cancelling.

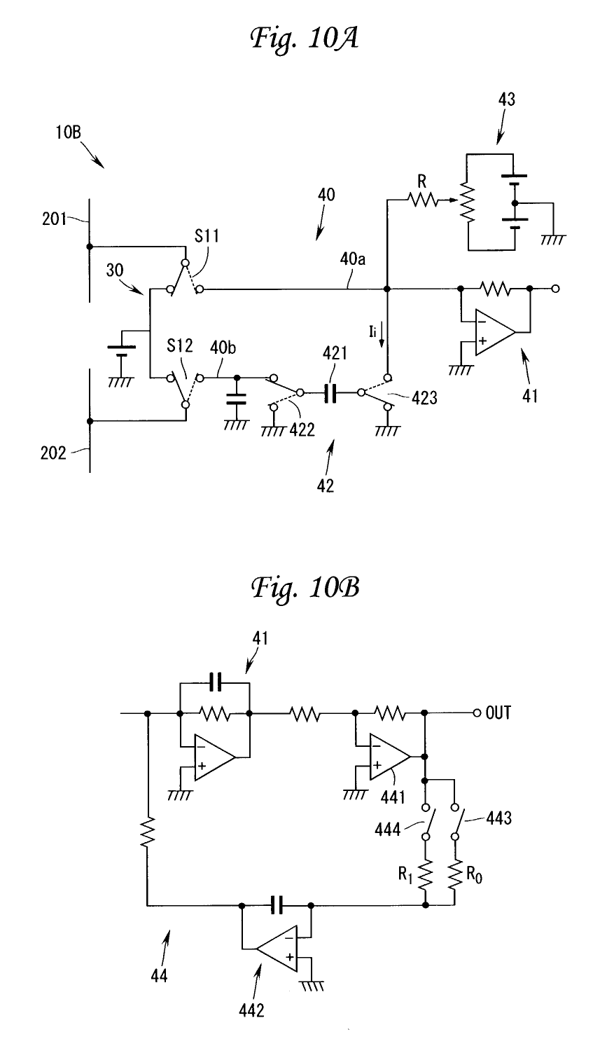

Furthermore, in the case where the external induction noise cannot completely be removed because of the size error or the arrangement error or the like of the detecting electrodes 201, 202, as shown in FIG. 10A, a DC bias circuit 43 made of a +, − power source and a variable resistance should be provided in the discharge system 40. In this case, the input side of the current-voltage converter 41 is made to be the imaginary earth, and therefore, even if the DC bias circuit 43 is added, the lowering of sensitivity is not produced.

Furthermore, as another method, as shown in FIG. 10B, it is also possible to provide a DC servo circuit 44 between the output side and the input side of the current-voltage converter 41. The DC servo circuit 44 comprises: a reversing circuit 441 for reversing the output of the current-voltage converter 41; an integral circuit 442 for returning the servo signal to the input side of the current-voltage converter 41; resistances R₀, R₁ (R₀<<R₁) provided in parallel between the reversing circuit 441 and the integral circuit 442; and two switches 443, 444 for selecting these.

The switch 443 on the low resistance R₀ side is a switch for making the response fast at the time of the loading of the power source, and at the normal operation time, it is set to off. The switch 444 on the high resistance R₁ side is a switch for making the offset be 0, and by control means (not shown in the drawing), if necessary, it is turned on. One way or the other, when the input side of the current-voltage converter 41 is shifted to, for example, the − side, a voltage for raising that to the + side is outputted from the integral circuit 442, and consequently, the offset is cancelled.

In both the above described proximity switches 10A, 10B, the charge and discharge of the electrostatic capacity possessed by the detecting electrode are the basic operation principle, and next, the embodiment of the proximity sensor of the present invention based on a balance circuit of the condenser will be described.

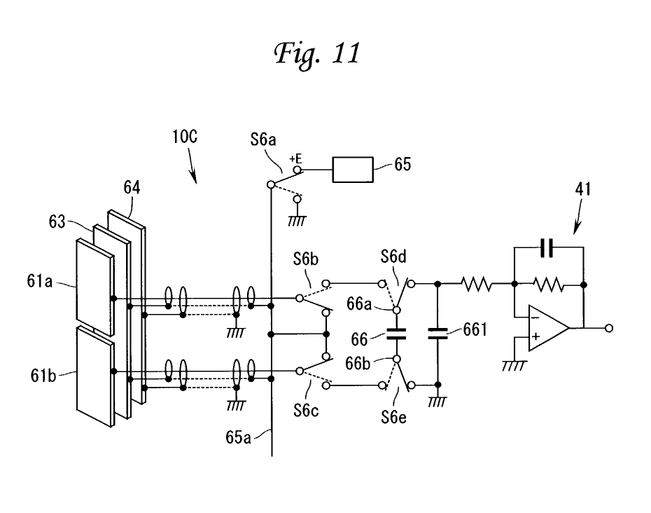

First, referring to FIG. 11, this proximity sensor 10C comprises: a first and second detecting electrodes 61a, 61b arranged on the same plane and made of a metal plate with the same size; and a drive electrode 63 arranged common to each of the detecting electrodes 61a, 61b on the rear side thereof, and in this embodiment, on the rear side of the drive electrode 63, furthermore, a ground electrode 64 is arranged. Furthermore, it is also possible that two drive electrodes 63 are arranged on the rear side of each of the detecting electrodes 61a, 61b.

In addition to this, this proximity sensor 10C comprises: a direct current power source 65 and a power source line 65a thereof; a condenser 66 for accumulating the electric charge of the difference of the electrostatic capacity of each of the detecting electrodes 61a, 61b; a current-voltage converter 41 for detecting the current supplied from the same condenser 66 as a voltage; and five switches S6a to S6e.

In this embodiment, the direct current power source 65 is used as an one-way power source, and the power source line 65a is alternately connected to +E (positive pole side) of the direct current power source 65 and the earth (electric potential is 0) through the switch 6a, and to the power source line 65a, a drive electrode 63 is connected. The first detecting electrode 61a is alternately switched and connected to the power source line 65a and one pole 66a of the condenser 66 through the switch 6b.

Furthermore, the second detecting electrode 61b is also alternately switched and connected to the power source line 65a and the other pole 66b of the condenser 66 through the switch 6c. Both poles 66a, 66b of the condenser 66 are alternately switched and connected to the detecting electrodes 61a, 61b side and the current-voltage converter 41 side through the switches 6d, 6e. Furthermore, in this embodiment, between the condenser 66 and the current-voltage converter 41, a balance condenser 661 is connected.

The switches S6a to S6e are switched synchronously by a specified switching frequency. That is, as shown by a solid line in the drawing, when the switch S6a is connected to the +E side of the direct current power source 65, synchronously with this, both the switches 6b, 6c are connected to the power source line 65a side, and both the switches 6d, 6e are connected to the current-voltage converter 41 side. Consequently, to the detecting electrodes 61a, 61b and the drive electrode 63, the same voltage is applied from the direct current power source 65.

On the other hand, as shown by a chain line in the drawing, when the switch S6a is connected to the earth side of the direct current power source 65, synchronously with this, both the switches 6b, 6c are connected to the condenser 66 side, and both the switches 6d, 6e are connected to the detecting electrodes 61a, 61b side.

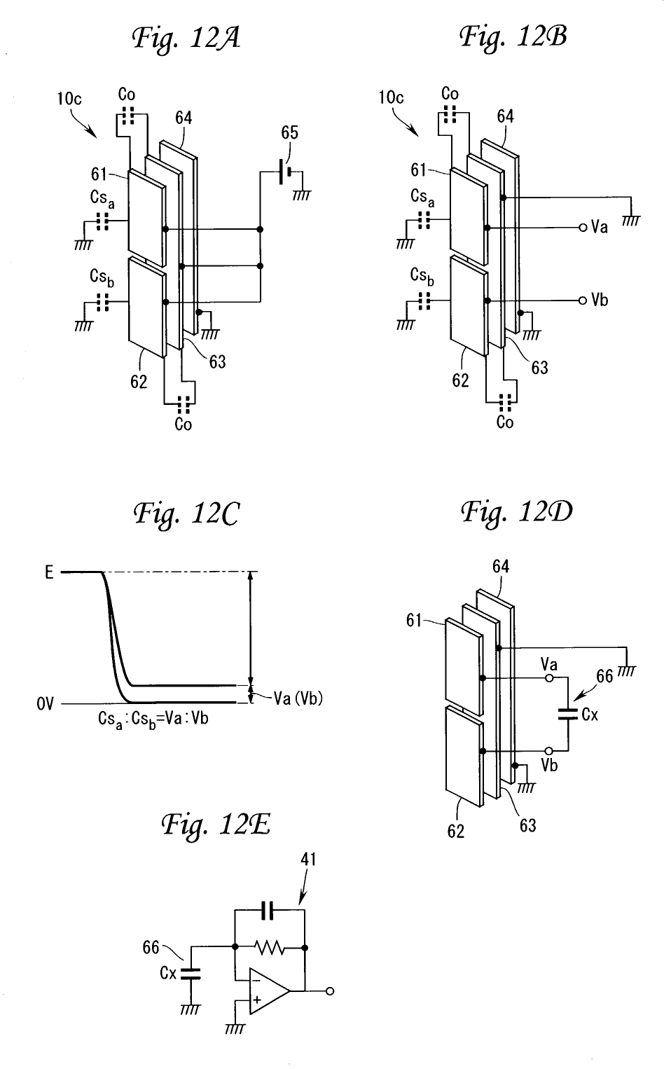

Next, referring to FIG. 12, the operation of this proximity sensor 10C will be described. First, when each of the switches S6a to S6e are in the switching state shown by the solid line in FIG. 11 and the detecting electrodes 61a, 61b and the drive electrode 63 are connected to the +E of the direct current power source 65, as shown in FIG. 12A, the detecting electrodes 61a, 61b and the drive electrode 63 becomes at the same electric potential, and the electrostatic capacity Co between them becomes 0. Furthermore, in the detecting electrodes 61a, 61b, the electric charges of Csa, Csb are respectively accumulated by the applied voltage +E.

Next, when each of the switches S6a to S6e are in the switching state shown by the chain line in FIG. 11 and the detecting electrodes 61a, 61b are separated from the direct current power source 65 to be connected to the condenser 66 and at the same time, the drive electrode 63 is dropped to the earth, as shown in FIG. 12B and FIG. 12C, to the detecting electrode 61a, a voltage Va made by being voltage-divided to the ratio of Co:Csa appears, and similarly, to the detecting electrode 61b, a voltage Vb made by being voltage-divided to the ratio of Co:Csb also appears. That is, the relation of Csa:Csb=Va:Vb is made.

Here, if a human body or the like approaches to the detecting electrodes 61a, 61b and Csa≠Csb, that is, Va≠ Vb is found, as shown in FIG. 12D, the difference Cx of the electric charge accumulated in the detecting electrodes 61a, 61b is transmitted to the condenser 66. Furthermore, it is supposed that the electrostatic capacity of the condenser 66 is sufficiently larger than the above described electrostatic capacity Co.

Again, if each of the switches S6a to S6e is in the switching state shown by the solid line in FIG. 11, as shown in FIG. 12D, the electric charge Cx accumulated in the condenser 66 is supplied to the current-voltage converter 41, and the electric charge of the condenser 66 becomes 0. By repeating this, the output corresponding to the difference of the electrostatic capacities Csa, Csb of each of the detecting electrodes 61a, 61b appears in the current-voltage converter 41.

According to this proximity sensor 10C, the circuit is symmetrical, and therefore, the electrical balance is good. On the detecting side of the current-voltage converter 41, only a minute current corresponding to the difference of the electric charge between the detecting electrodes 61a, 61b flows, and therefore, the S/N ratio is good. By providing the detecting electrodes 61a, 61b to one surface of the circuit board and arranging the drive electrode 63 on the other surface, it is possible to obtain such an advantage that the leading cable is unnecessary and the detecting part can be made to be one unit.

Furthermore, the switches S6a to S6e may be analog switches, or they may also be electronic switches such as an FET or a CMOS. In the above described embodiment, as for the direct current power source 65, it is a one-way power source of +E-earth, but naturally, it may also be a one-way power source of −E-earth, and furthermore, it may also be a bipolar power source of ±E.

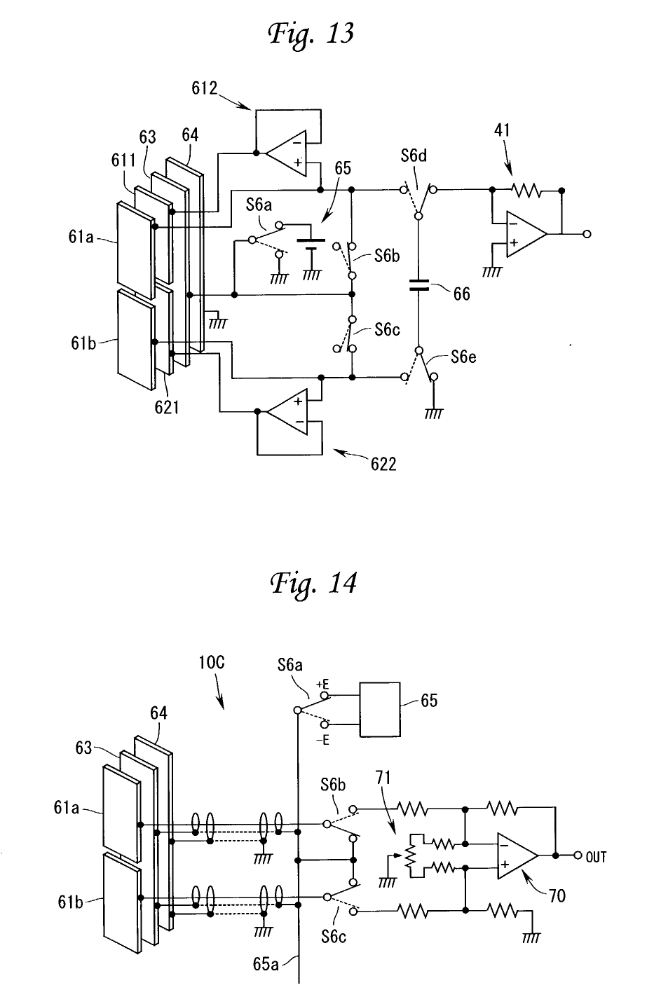

In this proximity sensor 10C, the following deformed example is included. That is, as shown in FIG. 13, between the detecting electrode 61a and the drive electrode 63, or between the detecting electrode 61b and the drive electrode 63, a first and a second guard electrodes 611, 621 made of a metal plate with the same size as the detecting electrodes 61a, 61b are arranged, respectively.

Then, the first detecting electrode 61a and the first guard electrode 611 are connected through an operation amplifier 612 with an amplification factor of one time, and furthermore, similarly, the second detecting electrode 61b and the second guard electrode 621 are connected through an operation amplifier 622 with an amplification factor of one time.

According to this, the effects of the leading cable can almost completely be removed. Furthermore, in this deformed example, it is also possible that there is no drive electrode 63, but from the viewpoint of the stability, it is preferable that there is a drive electrode 63.

Furthermore, as shown in FIG. 14, it is also possible to receive the output of the detecting electrodes 61a, 61b obtained through the switches S6b, S6c by a differential amplifier 70. Furthermore, between the input terminals of the differential amplifier 70, a variable resistance 71 for compensating the dispersion of the terminal point resistance of the switches S6b, S6c or the like is connected.

Next, the proximity sensor 10D shown in FIG. 15 will be described. This proximity sensor 10D is technically positioned at the same line as the proximity sensor 10C described in FIG. 11, and accordingly, the same reference marks are used for the same structural components as the structural components of the proximity sensor 10C or the structural components which can be regarded as the same.

In this proximity sensor 10D, the direct current power source 65 is used, for example, as a bipolar power source of +E and −E. Furthermore, letting the above described condenser 66 be the first condenser, a second condenser 67 which is provided on the input side (detecting electrode side) of this first condenser 66 and is connected in parallel to the first condenser 66 through the switches 6d, 6e is provided.

In this proximity sensor 10D, only the drive electrode 63 is arranged to be connected to the direct current power source 65 through the switch S6a, and the detecting electrodes 61a, 61b are alternately switched and connected to one pole 67a and the other pole 67b of the second condenser 67 through the switches S6b, S6c.

The switches S6a to S6e are synchronously switched by a specified switching frequency, and in this case, if the switching frequency of the switch S6a is f, the switches S6b, S6c are switched by the same frequency f, and the switches S6d, S6e are preferably switched by a frequency 2 f of two times that frequency.

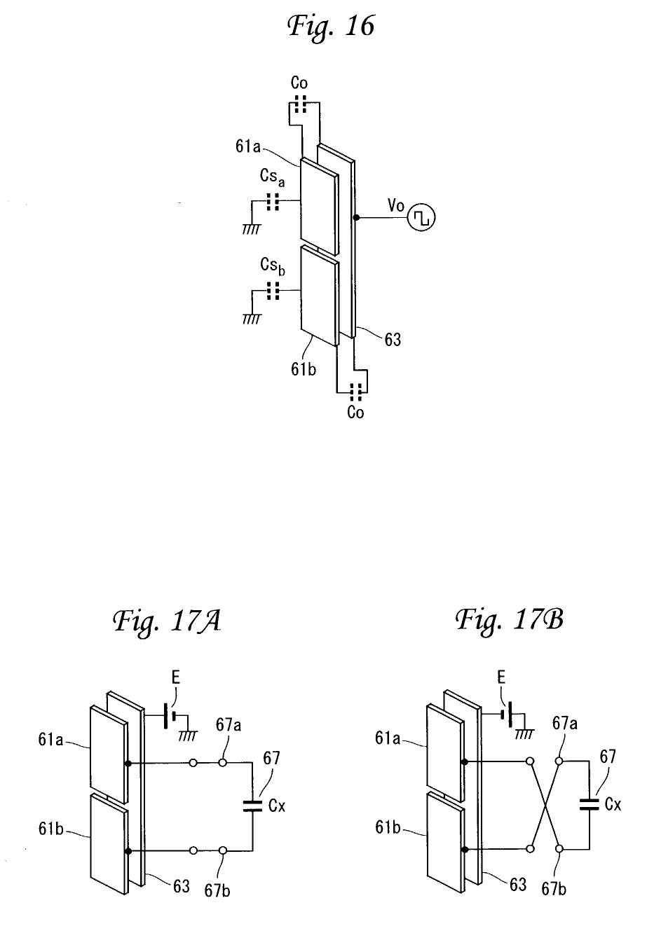

Referring to FIG. 16, letting the voltage applied from the direct current power source 65 to the drive electrode 63 be Vo, and the electrostatic capacity produced between the drive electrode 63 and each of the detecting electrodes 61a, 61b be Co, and the electrostatic capacities between the detecting electrodes 61a, 61b and for example, the earth be Csa, Csb respectively, the induction voltages Va, Vb of the detecting electrodes 61a, 61b and the voltage Vo have the following proportional relation:

Co:Csa=Vo:(Vo−Va)

Co:Csb=Vo:(Vo−Vb)

Next, one example of the operation of this proximity sensor 10D will be described. First, as shown in FIG. 17A, when the drive electrode 63 is connected to the +E side of the direct current power source 65 by the switch S6a, the detecting electrode 61a is connected to one pole 67a of the second condenser 67 by the switch S6b, and the detecting electrode 61b is connected to the other pole 67b of the second condenser 67 by the switch S6c. Furthermore, the first condenser 66 is separated from the second condenser 67, and is connected to the current-voltage converter 41 side by the switches S6d, S6e.

Next, as shown in FIG. 17B, when the drive electrode 63 is connected to the −E side of the direct current power source 65 by the switch S6a, the detecting electrode 61a is connected to the other pole 67b of the second condenser 67 by the switch S6b, and the detecting electrode 61b is connected to one pole 67a of the second condenser 67 by the switch S6c. At this moment, the first condenser 66 is also kept in the state of being connected to the current-voltage converter 41 side.

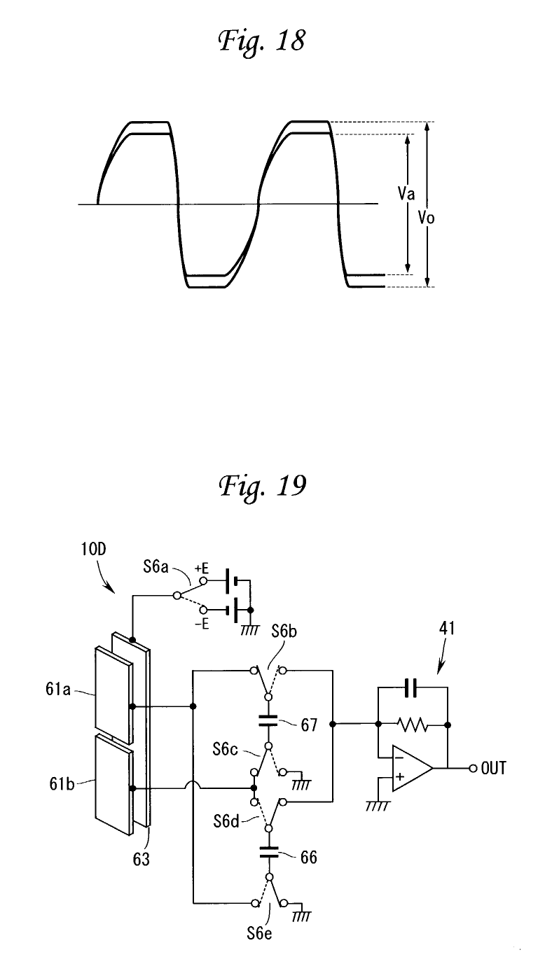

Thus, the synchronous detection is performed in synchronization with the switching of the power source to the drive electrode 63. In FIG. 18, the synchronous detection waveform of one detecting electrode 61a is shown. Consequently, in the second condenser 67, the electric charge Cx of the difference of the induction voltages Va, Vb of the detecting electrodes 61a, 61b is accumulated.

Then, when the drive electrode 63 is again connected to the +E side of the direct current power source 65, the switches S6d, S6e are switched to the second condenser 67 side, and the electric charge Cx thereof is transmitted to the first condenser 66, and at a specified timing point after that, the switches S6d, S6e are switched to the current-voltage converter 41 side.

Furthermore, the second condenser 67 is positioned at the front step of the first condenser 66, and therefore, it is also possible that the switching frequency of the switches S6d, S6e is the same as other switches S6a to S6c, and in that case, the circuit of the proximity sensor 10D can be re-arranged as shown in FIG. 19.

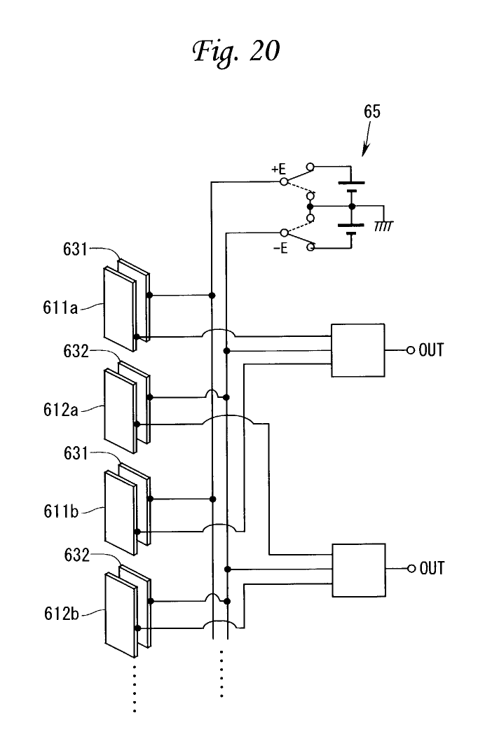

The above described proximity sensors 10C, 10D have a pair of detecting electrodes 61a, 61b as the minimum unit, and to each of them, a drive electrode 63 is provided, but when a plurality of pairs of detecting electrodes are arranged to be used, in order to reduce the noise emitted from the drive electrode 63, as shown in FIG. 20, letting the detecting electrodes 611a and 611b be a pair, and the detecting electrodes 612a and 612b be a pair, it is preferable that they are alternately arranged, and the polarity of the voltage applied to each of these drive electrode 631 and drive electrode 632 is alternately replaced.

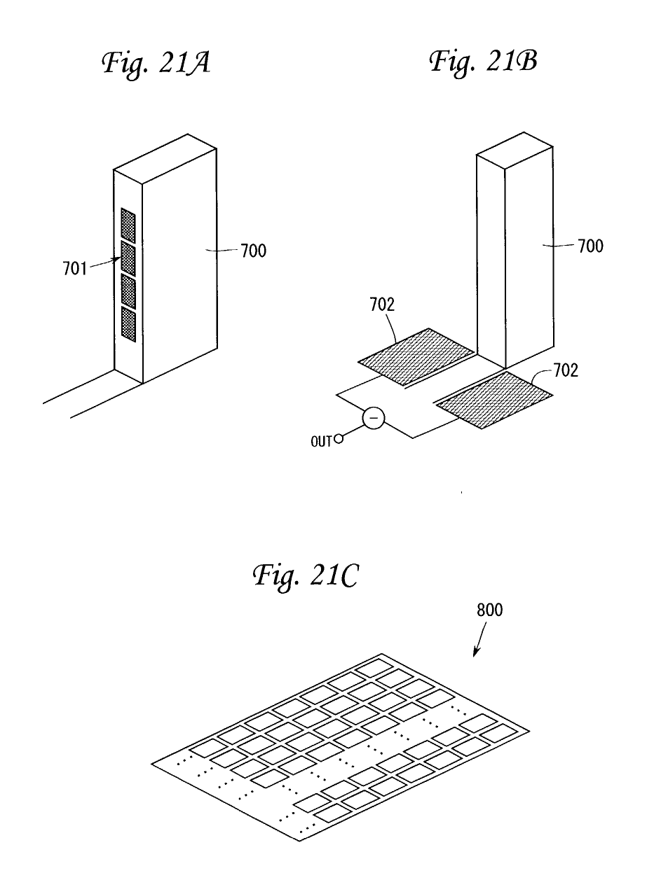

In the present invention, an object detecting device made by alternately arranging a plurality of combinations of any one of the above described proximity sensors 10B, 10C, 10D along a specified plane or a curved surface is included, and as the use thereof, for example, as shown in FIG. 21A, there is a sensor 701 of the leading edge of door leaf of an automatic door 700. Furthermore, as shown in FIG. 21B, it can be used as a mat sensor 702 of the automatic door 700.

Furthermore, as shown in FIG. 21C, it is also possible that each detecting electrode is arranged like a matrix to be a plane sensor 800. Especially, according to this plane sensor 800, not only the simple object detection can be performed but also the detection of where the object is positioned can be performed.

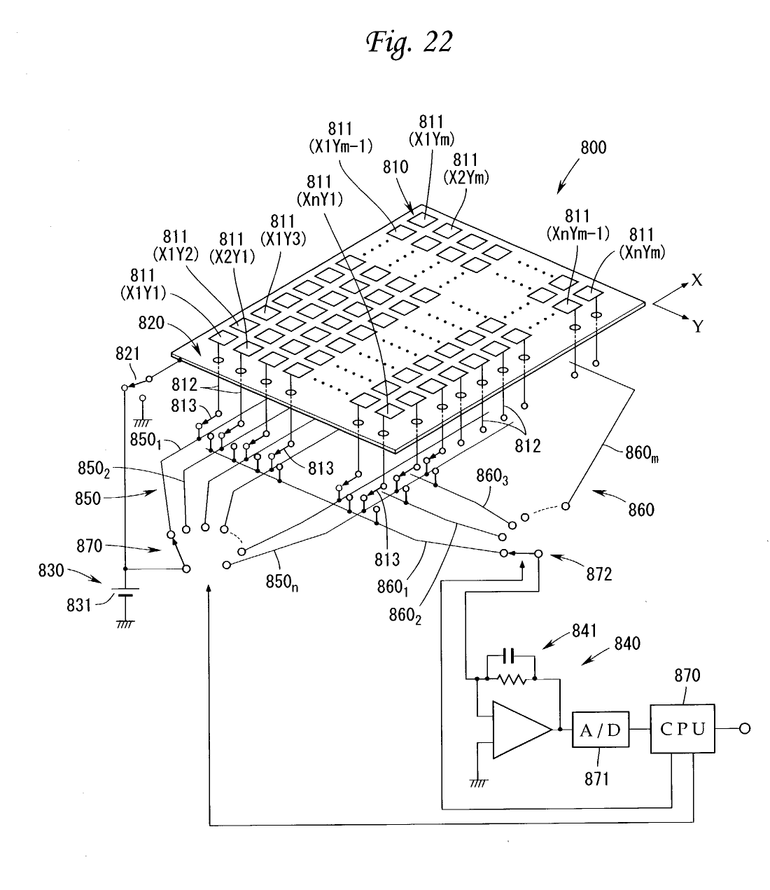

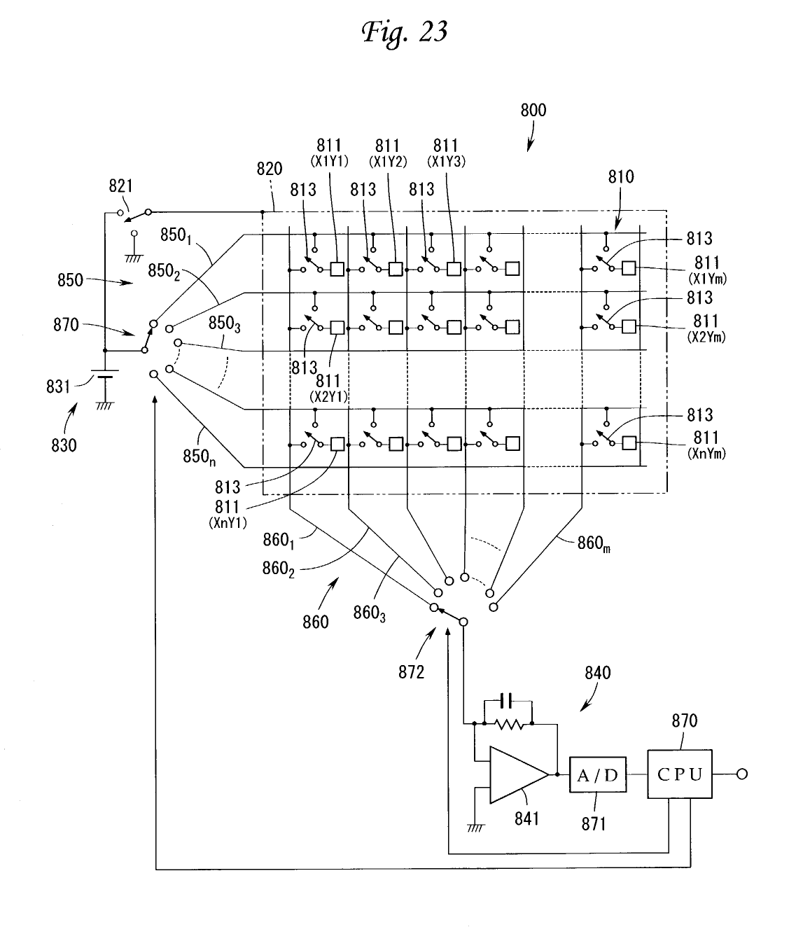

Next, referring to the typical perspective view of FIG. 22 and the wiring diagram of FIG. 23, the configuration of a plane sensor 800 shown in FIG. 21C will more particularly be described including the drive system thereof. This plane sensor 800 has a sensor surface 810 including a plurality of detecting electrodes 811 arranged in parallel like a matrix along the line direction (X-direction) and the row direction (Y-direction) on the same plane.

Furthermore, supposing that the number of lines is X1 to Xn, and the number of rows is Y1 to Ym (m and n are optionally selected integers of 2 or more), in the following description, in the case where it is necessary to indicate an individual detecting electrode, the marks X, Y are used for expressing the position, and in the case where the common item of each detecting electrode is explained, the mark 811 as the general term is used.

For each detecting electrode 811, a plate-like metal plate is used, and the size thereof is properly selected according to the use of this plane sensor 800. For example, in case of being arranged on the floor surface in the room for detecting the existence of a human body or the walking direction, it may approximately be a size of a human foot.

As another example, if it is used for detecting a human finger print, the plane sensor 800 itself has a so-called stamp size, and therefore, each detecting electrode 811 has a size of micron order (μm). For the support plate of each detecting electrode 811, for example, a glass board or a synthetic resin board is used, which is not shown in detail in FIG. 22, and on that support plate, each detecting electrode 811 is arranged like a matrix as mentioned above. Furthermore, in the case where a small-sized sensor such as a finger print sensor is made, it is sufficient to form a metal film as a detecting electrode on a silicon wafer, for example, by the evaporation method or the spattering method.

On the rear side of the sensor surface 810, a drive electrode 820 is arranged through a specified dielectric layer (not shown in the drawing). For the drive electrode 820, a plate-like metal plate is also used, but the size thereof is the same as the sensor surface 810 or larger than that. The dielectric layer put between the sensor surface 810 and the drive electrode 820 becomes the synthetic resin board as the support plate of the sensor surface 810, but in addition to that, furthermore, another synthetic resin board or a layer of air may be put.

This plane sensor 800 also comprises a charge system 830 with a direct current power source 831 and a discharge system 840 with a current-voltage converter 841 (current detecting means) as the current detecting means, but in order to make it possible to obtain detected information from the individual detecting electrode 811, the following means is taken.

That is, along the line direction (X-direction) of the sensor surface 810, the charge wirings 850(850₁ to 850ₙ) of the same number as the number of lines thereof are provided, and furthermore, along the row direction (Y-direction) of the sensor surface 810, the discharge wirings 860 (860₁ to 860ₘ) of the same number as the number of row thereof are provided. The charge wirings 850 and the discharge wirings 860 are both arranged on the anti-sensor surface side (lower side in FIG. 22) of the drive electrode 820.

Between the charge wiring 850 and the charge system 830, a first scanner switch 871 for sequentially connecting each of the charge wirings 850₁ to 850ₙ to the direct current power source 931 of the charge system 830 is provided, and furthermore, between the discharge wiring 860 and the discharge system 840, a second scanner switch 872 for sequentially connecting each of the discharge wirings 860₁ to 860ₘ to the current-voltage converter 841 of the discharge system 840 is provided.

Each detecting electrode 811 has a leading wire 812 penetrating the drive electrode 820 in the electric insulating state to be drawn out downward, and to each leading wire 812, a detecting electrode switching switch 813 to be switched selectively to the charge wiring 850 and the discharge wiring 860 is provided. Making description by taking the detecting electrode (X1Y1) as an example, this detecting electrode (X1Y1) is selectively connected to either the charge wiring 850₁ or the discharge wiring 860₁ by the detecting electrode switching switch 813.

Furthermore, this plane sensor 800 has a drive electrode switching switch 821 and control means (CPU) 870 connected to the output side of the current-voltage converter 841 of the discharge system 840 through the A/D converter 871. The drive electrode switching switch 821 selectively connects the drive electrode 820 to the direct current power source 831 of the charge system 830 and the earth.

The CPU 870 receives the detected information of each detecting electrode 811 which is obtained from the discharge system 840 to perform various judgments. For example, in the case where this plane sensor 800 is a finger print sensor, it compares the previously registered finger print data with the detected finger print data, or re-creates a finger print by that detected finger print data to express that on a printer, a display or the like (not shown in the drawing). Furthermore, the CPU 870 controls each switch as follows, when collecting the detected information from each detecting electrode 811.

The first scanner switch 871 sequentially switches and connects each of the charge wirings 850₁ to 850ₙ to the direct current power source 931, and for example, when the first charge wiring 850, is selected, synchronously with this, it switches the drive electrode switching switch 821 to the direct current power source 931 side, and at the same time, it switches each detecting electrode switching switch 813 of the detecting electrodes (X1Y1) to (X1Ym) of the first line to the charge wiring 850₁ side. Consequently, the detecting electrodes (X1Y1) to (X1Ym) of the first line and the drive electrode 820 has the same electric potential, and the drive electrode 820 acts as one kind of active shield plate, and therefore, without receiving the effects of the noise from the anti-sensor surface side (circuit side), and the electrostatic capacity produced between each of the detecting electrodes (X1Y1) to (X1Ym) and the detected object can accurately be detected.

Furthermore, the electrostatic capacity between each of the detecting electrodes (X1Y1) to (X1Ym) and the circuit on the anti-sensor surface side becomes substantially 0, and therefore, the electric supply to the unnecessary capacity is removed, and the S/N ratio is largely improved. Furthermore, accompanied with the improvement of the S/N ratio, the protecting layer of the sensor surface can be made thick, and the mechanical strength can also be increased.

After the charge (electric power supply) has been performed for a specific time as described above, the drive electrode switching switch 821 is switched to the earth side, and furthermore, each detecting electrode switching switch 813 of the detecting electrodes (X1Y1) to (X1Ym) of the first line is switched to the discharge wiring 860₁. After that, the second scanner switch 872 is sequentially switched to the discharge wirings 860₁ to 860ₘ to go around.

Consequently, the current based on each electrostatic capacity of the detecting electrodes (X1Y1) to (X1Ym) of the first line is sequentially taken in the CPU 870 through the current-voltage converter 841 and the A/D converter 871.

Next, each time the first scanner switch 871 is sequentially switched to the second charge wiring 850₂→the third charge wiring 850₃→ . . . →the charge wiring 850ₙ with the ordinal number n, the drive electrode switching switch 821, the detecting electrode switching switch 813, and the second scanner switch 872 are switched as described above, and the detected information is taken in the CPU 870 from each detecting electrode 811.

Furthermore, in the case of the above described example, the charge wiring 850 is wired in the line direction (X-direction) and the discharge wiring 860 is wired in the row direction, but it is also possible that on the contrary, the discharge wiring 860 is wired in the line direction (X-direction) and the charge wiring 850 is wired in the row direction.

Furthermore, each switch may be either a mechanical switch or an electronic switch, but in the above described each embodiment, in the case where the switching frequency of the switch for switching the charge system and the discharge system is fixed, there is such a possibility that the harmonics thereof give obstruction to the radio receiver or the like. For example, in the case where the switching frequency of the switch is a rectangular wave of 64 kHz, many harmonics are included in that, and the tenth order component among them is 640 kHz, and this is outputted at all times. Accordingly, in the case where 640 kHz is included in the receiving frequency of the radio receiver or the like, it becomes a wave of obstruction.

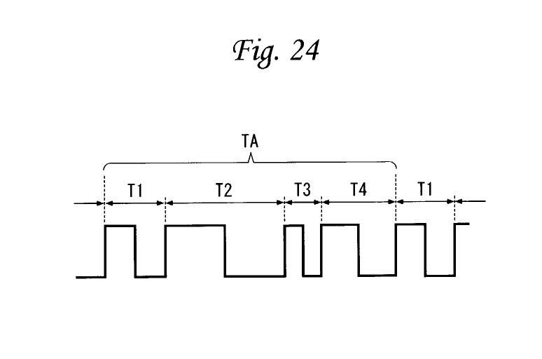

In order to prevent this, as shown in FIG. 24, it is preferable that the frequency for switching the charge system and the discharge system is made to be, for example, a complex frequency TA including four different frequencies T1 to T4, and this is repeatedly used. As one example, in the case where the complex frequency TA is made to be a combination of 64, 65, 66, 67 (kHz), as the tenth order component, 640, 650, 660, 670 (kHz) are alternately outputted, and therefore, the obstruction to the radio receiver or the like can be reduced.

1. A proximity sensor comprising:
a detecting electrode arranged in an object detecting area and made of a metal plate formed like a plate;
a charge system with a direct current power source;
a discharge system with current detecting means; and
a switch for alternately switching said charge system and said discharge system to said detecting electrode by a specified switching frequency,
wherein an electrostatic capacity between a detected object and said detecting electrode is detected as current (Is) flowing in said discharge system.

2. The proximity sensor according to claim 1, wherein an earthed ground electrode is arranged facing to said detecting electrode, and at the same time, a current source for absorbing current (Io) corresponding to the increase flowing in said discharge system because of electrostatic capacity between said ground electrode and said detecting electrode is provided in parallel to said current detecting means.

3. The proximity sensor according to claim 1, wherein an earthed ground electrode is arranged facing to said detecting electrode, and at the same time, to said discharge system, a capacitor with the same capacity as the electrostatic capacity between said ground electrode and said detecting electrode; a second direct current power source with a polarity reverse to that of the direct current power source of said charge system; and a second switch for alternately switching said second direct current power source and said discharge system to said capacitor in synchronization with said switch are provided.

4. The proximity sensor according to claim 3, wherein as said capacitor, a pair of electrode plates made of the same combination as said detecting electrode and said ground electrode are used.

5. A proximity sensor comprising:
a detecting electrode arranged in an object detecting area and made of a metal plate formed like a plate;
an earthed ground electrode arranged facing to the same detecting electrode;
a charge system with a direct current power source; a discharge system with current detecting means; and
a double shield wire with an inside skin shield and an outside skin shield around a central conductor,
wherein said detecting electrode is connected to one end of said central conductor, and to the other end side thereof, a first switch for alternately switching said charge system and said discharge system to the same central conductor by a specified switching frequency, and at the same time, to said inside skin shield, a second switch for alternately switching the same inside skin shield to said charge system and the earth in synchronization with said first switch is provided, and said ground electrode is connected to said outside skin shield.

6. The proximity sensor according to claim 5, wherein between said detecting electrode and said ground electrode, a guard electrode is arranged, and said guard electrode is connected to said inside skin shield.

7. A proximity sensor comprising:
a first and a second detecting electrodes both of which are made of a metal plate with the same size formed like a plate, and are set in parallel approximately on the same plane in an object detecting area;
a charge system with a direct current power source;
a discharge system with current detecting means; and
switch means for alternately switching both said first and second detecting electrodes to said charge system and said discharge system by a specified switching frequency.

8. The proximity sensor according to claim 7, wherein when connecting both said first and second detecting electrodes to said charge system, one detecting electrode is connected to the positive pole side of the direct current power source, and the other detecting electrode is connected to the negative pole of the direct current power source, and when connecting both said first and second detecting electrodes to said discharge system, current (Isa) obtained from said one detecting electrode and current (Isb) obtained from said the other detecting electrode are added in said discharge system.

9. The proximity sensor according to claim 7, wherein when connecting both said first and second detecting electrodes to said charge system, each detecting electrode thereof is connected to the same pole side of the direct current power source, and when connecting both said first and second detecting electrodes to said discharge system, current (Isa) obtained from one detecting electrode and current (Isb) obtained from the other detecting electrode are subjected to relatively subtraction in said discharge system.

10. A proximity sensor comprising:
a first and a second detecting electrodes both of which are made of a metal plate with the same size formed like a plate, and are set in parallel approximately on the same plane in an object detecting area;
a charge system with a direct current power source;
a discharge system with current detecting means; and
main switch means for alternately switching both said first and second detecting electrodes to said charge system and said discharge system by a specified switching frequency,
wherein said discharge system is provided in parallel between said main switch means and said current detecting means, and comprises: a first discharge circuit connected to said first detecting electrode side; and a second discharge circuit connected to said second detecting electrode side, and to said one discharge circuit, a signal reversing circuit made of a capacitor and a sub switch for alternately separating both ends of the same capacitor from the same discharge circuit to connect the ends to the earth terminal is provided, and each time said main switch means is switched, the polarity of said capacitor is reversed by said sub switch.

11. A proximity sensor comprising:
a first and a second detecting electrodes both of which are made of a metal plate with the same size formed like a plate, and are set in parallel approximately on the same plane in an object detecting area;
a drive electrode arranged facing common to each of the detecting electrodes;
a charge system with a direct current power source;
a discharge system with a condenser and current detecting means;
a first switch for selectively connecting at least one pole of said direct current power source to said drive electrode by a specified switching frequency;
a second switch for alternately connecting each of said detecting electrodes together to said the same pole of said direct current power source and said condenser in synchronization with the same first switch; and
a third switch for alternately connecting said condenser to said each detecting electrode and said current detecting means in synchronization with said each switch.

12. The proximity sensor according to claim 11, wherein among said first and second detecting electrodes and said drive electrode, a first and a second guard electrodes made of a metal plate with the same size as said detecting electrode are arranged, and said first detecting electrode and said first guard electrode, and said second detecting electrode and said second guard electrode are respectively connected through an operation amplifier with an amplification factor of one time.

13. A proximity sensor comprising:
a first and a second detecting electrodes both of which are made of a metal plate with the same size formed like a plate, and are set in parallel approximately on the same plane in an object detecting area;
a drive electrode arranged facing common to each of the detecting electrodes;
a charge system with a direct current power source;
a discharge system with a first and a second condensers and current detecting means;
a first switch for selectively connecting at least one pole of said direct current power source to said drive electrode by a specified switching frequency;
a second switch for synchronous detection for alternately replacing and connecting each of said detecting electrodes to both poles of said first condenser in synchronization with the same first switch; and
a third switch for alternately connecting said second condenser to said first condenser and said current detecting means in synchronization with said each switch.

14. The proximity sensor according to claim 13, wherein the switching frequency of said third switch is set at two times the switching frequency of said first and second switches.

15. An object detecting device comprising a plurality of combinations of proximity sensors according to any one of claims 7 to 14,
wherein each detecting electrode of adjacent combinations is alternately arranged along a specified plane or a curved surface.

16. An object detecting device comprising a plurality of combinations of proximity sensors according to any one of claims 7 to 14,
wherein each detecting electrode of adjacent combinations is alternately arranged along a specified plane or a curved surface, and a drive voltage with a different polarity is applied to a detecting electrode with an odd ordinal number and a detecting electrode with an even ordinal number.

17. An object detecting device for automatic door opening and closing control, comprising a plurality of combinations of proximity sensors according to any one of claims 7 to 14,
wherein each detecting electrode of adjacent combinations is alternately arranged along a leading edge of door leaf of an automatic door.

18. An object detecting device for automatic door opening and closing control, comprising a plurality of combinations of proximity sensors according to any one of claims 7 to 14,
wherein each detecting electrode of adjacent combinations is alternately arranged on the entrance floor surface of an automatic door.

19. An object detecting device comprising:
a sensor surface including a plurality of detecting electrodes set in parallel along the line direction and the row direction on the same plane;
a drive electrode arranged approximately through the total surface on the rear side of said sensor surface through a dielectric layer;
a charge system with a direct current power source;
a discharge system with current detecting means;
a plurality of charge wirings wired along either the line direction of said sensor surface or said row direction on the anti-sensor surface side of said drive electrode and a plurality of discharge wirings wired along the other;
a detecting electrode switching switch for selectively connecting said each detecting electrode separately to either said charge wiring or said discharge wiring;
a first scanner switch for sequentially connecting said each charge wiring to the direct current power source of said charge system;
a second scanner switch for sequentially connecting said each discharge wiring to the current detecting means of said discharge system;
a drive electrode switching switch for selectively connecting said drive electrode to either the direct current power source of said charge system or the earth; and
control means for controlling said each switch,
wherein each time said charge wiring is connected to said direct current power source one by one, by switching said first scanner switch, said control means performs:
a first step of switching said drive electrode switching switch to said direct current power source side, and of simultaneously switching said detecting electrode switching switch selected by said first scanner switch and existing along said charge wiring, to the same charge wiring side;
a second step of switching said drive electrode switching switch to said earth side after said first step, and of simultaneously switching said detecting electrode switching switch switched to said charge wiring side at said first step, to said discharge wiring side; and
a third step of sequentially switching said second scanner switch to go around after said second step.

20. The proximity sensor according to any one of claims 1 to 14, or the object detecting device according to any one claims 15 to 19,
wherein for the switching frequency of a switch for switching said charge system and said discharge system, a complex frequency including a plurality of different frequencies is repeatedly used.
